(19) United States
(12) Patent Application Publication
(10) Pub. No.: US 2026/0150553 A1
(43) Pub. Date: May 28, 2026

(54) ELECTRONIC DEVICE

(71) Applicant: Samsung Display Co., Ltd., Yongin-si (KR)

(72) Inventors: HEEYOUNG LEE, Yongin-si (KR); SUNGGUK AN, Yongin-si (KR); RAE-YOUNG KIM, Yongin-si (KR); Jungwook KIM, Yongin-si (KR); GILYEONG PARK, Yongin-si (KR); Jimi EOM, Yongin-si (KR); JEWON YOO, Yongin-si (KR); SOYEON HAN, Yongin-si (KR)

(21) Appl. No.: 19/402,902

(22) Filed: Nov. 26, 2025

(30) Foreign Application Priority Data
Nov. 28, 2024 (KR) 10-2024-0173286

(51) Int. Cl. H10K 59/80; H04M 1/02

(52) U.S. Cl. CPC H10K 59/8722; H04M 1/0216; H10K 59/8731

(57) ABSTRACT

A display device and an electronic device including the display device are disclosed. The display device may include a display layer including a plurality of light-emitting elements, an optical layer on the display layer, and a window on the optical layer, wherein the window includes a thin film glass layer, a film layer disposed or provided on the thin film glass layer and having a first refractive index, a first protective layer disposed or provided on the film layer and having a second refractive index, and a plurality of adhesive layers, each in contact with at least any one of the thin film glass layer, the film layer, or the first protective layer, and each having a third refractive index, wherein the difference of the first refractive index for each wavelength is about 0.2 or less.

### CROSS-REFERENCE TO RELATED APPLICATION

The present application claims priority to and the benefit of Korean Patent Application No. 10-2024-0173286, filed on Nov. 28, 2024, in the Korean Intellectual Property Office, the entire disclosure of which is incorporated herein by reference.

### BACKGROUND

### 1. Field

One or more embodiments of the present disclosure relate to a display device and an electronic device including the display device that have improved or enhanced display quality.

### 2. Description of the Related Art

Multimedia electronic apparatuses, such as televisions, mobile phones, tablet computers, navigation systems, and game consoles, have an electronic device to display images. The electronic device may include an organic light-emitting electronic device. The organic light-emitting electronic device includes a light-emitting element, and the light-emitting element may generate light through the recombination of electrons and holes. The organic light-emitting electronic device has the advantages or benefits of having a fast response speed and being driven with low power consumption.

### SUMMARY

One or more aspects of embodiments of the present disclosure are directed toward a display device and an electronic device including the display device that have improved or enhanced display quality by decreasing the reflectance of external light (or reducing a degree or occurrence of the reflectance of external light) and reducing reflective color defects caused by color deviation (or reducing a degree or occurrence of reflective color defects caused by color deviation).

Additional aspects of embodiments will be set forth in part in the description which follows and, in part, will be apparent from the description, or may be learned by practice of the presented embodiments of the disclosure.

One or more embodiments of the present disclosure provide a display device including a display layer including a plurality of light-emitting elements, an optical layer on the display layer, and a window on the optical layer, wherein: the optical layer includes a light blocking layer having a plurality of openings defined therein and corresponding to a plurality of light-emitting regions and a plurality of color filters disposed or provided to correspond to the plurality of openings, respectively; the window includes a thin film glass layer, a film layer disposed or provided on the thin film glass layer and having a first refractive index, a first protective layer disposed or provided on the film layer and having a second refractive index, and an adhesive layer in contact with any one selected from among the thin film glass layer, the film layer, and the first protective layer and having a third refractive index; and the difference between the maximum and minimum values of the first refractive index measured within a wavelength range of about 450 nm to about 650 nm is about 0.2 or less.

In one or more embodiments, on substantially the same wavelength, the difference between the refractive index of the thin film glass layer and each of the first refractive index, the second refractive index, and the third refractive index may be about 0.05 or less.

In one or more embodiments, the adhesive layer may be in contact with each of the film layer and the thin film glass layer, and the thickness of the adhesive layer may be about 50 μm or less.

In one or more embodiments, a display device may further include a second protective layer below the film layer, and the film layer may include triacetyl cellulose (TAC).

In one or more embodiments, the optical layer may further include a planarization layer covering the color filters and the light blocking layer, and the adhesive layer may be disposed or provided between the film layer and the planarization layer and in contact with the planarization layer.

In one or more embodiments, a display device may further include fluorine in the second protective layer.

In one or more embodiments, the second protective layer may have elasticity.

In one or more embodiments, the modulus of the second protective layer may be about ½ or less of the modulus of the film layer.

In one or more embodiments, the thickness of the second protective layer may be about 5 μm to about 50 μm.

In one or more embodiments, on substantially the same wavelength, the difference between the refractive index of the planarization layer and the first refractive index may be about 0.05 or less.

In one or more embodiments, the first protective layer may be in contact with the film layer, and the thickness of the first protective layer may be about 5 μm or less.

In one or more embodiments, on substantially the same wavelength, the first to third refractive indices may be substantially the same as each other.

In one or more embodiments, an electronic device includes a plurality of housing units, each providing a set or predetermined accommodation space, a hinge unit disposed or provided between the housing units and connecting the housing units to each other, and a display device accommodated in the set or predetermined accommodation space, wherein the display device includes a display layer including a plurality of light-emitting elements, an optical layer on the display layer, and a window on the optical layer, wherein: the optical layer includes a light blocking layer having a plurality of openings defined therein and corresponding to a plurality of light-emitting regions, a plurality of color filters disposed or provided to correspond to the plurality of openings, respectively, and a planarization layer covering the color filters; and the window includes a thin film glass layer, a film layer disposed or provided on the thin film glass layer and having a first refractive index, a first protective layer disposed or provided on the film layer and having a second refractive index, and an adhesive layer in contact with at least any one of the thin film glass layer, the film layer, or the first protective layer and having a third refractive index, wherein, on substantially the same wavelength, the difference between the refractive index of the planarization layer, the refractive index of the thin film glass layer, and the first refractive index is about 0.05 or less. In one or more embodiments, on substantially the same wavelength, each of a difference between a refractive index of the planarization layer and the first refractive index of the film layer and a difference between a refractive index of the thin film glass layer and the first refractive index of the film layer may be about 0.05 or less.

In one or more embodiments, on substantially the same wavelength, the difference between the third refractive index and the refractive index of the thin film glass layer may be about 0.05 or less.

In one or more embodiments, the difference between the maximum and minimum values of the first refractive index measured within a wavelength range of about 450 nm to about 650 nm may be about 0.2 or less.

In one or more embodiments, an electronic device may further include a second protective layer between the film layer and the optical layer, and the adhesive layer may be in contact with each of the second protective layer and the planarization layer.

In one or more embodiments, the thickness of the second protective layer may be about 5 μm to about 50 μm.

In one or more embodiments, the first protective layer may be in contact with the film layer.

In one or more embodiments, the first protective layer may further include a low reflection layer, and the refractive index of the low reflection layer may be about 1.48 or less.

In one or more embodiments, the thickness of the thin film glass layer may be about 30 μm or less.

In one or more embodiments, on substantially the same wavelength, each of the first to third refractive indices may be substantially equal to the refractive index of the thin film glass layer.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of the subject matter of the present disclosure. In the drawings:

FIG. 1A is a perspective view of an electronic device according to one or more embodiments;

FIG. 1B is a block diagram of an electronic device according to one or more embodiments;

FIG. 2 is a perspective view of an electronic device according to one or more embodiments;

FIG. 3 is a cross-sectional view of a display device according to one or more embodiments;

FIG. 4 is an enlarged plan view illustrating a partial region of a display layer according to one or more embodiments;

FIG. 5 is a cross-sectional view illustrating a portion of an electronic device according to one or more embodiments;

FIG. 6 is a cross-sectional view illustrating a portion of an electronic device according to one or more embodiments;

FIG. 7A is a graph illustrating changes in refractive index according to the wavelengths of layers constituting an optical layer;

FIG. 7B is a graph illustrating changes in refractive index according to the wavelengths of Comparative Embodiment; and

FIG. 7C is a graph illustrating changes in reflectance according to the wavelengths of Comparative Embodiment.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout the attached drawings and the written description, and duplicative descriptions thereof may not be provided in the specification.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As used herein, the singular forms “a,” “an,” and “the” are intended to include the plural forms as well, unless the context clearly indicates otherwise. The singular expression includes the plural expression unless the context clearly dictates otherwise.

As used herein, the term “and/or” or “or” includes any and all combinations of one or more of the associated listed items.

Throughout the present disclosure, the expressions, such as “at least one of,” “one of,” and “selected from,” if (e.g., when) preceding a list of elements, modify the entire list of elements and do not modify the individual elements of the list. For example, “at least one of a, b, or c,” “at least one selected from among a, b, and c,” “at least one selected from among a to c,” and/or the like indicates only a, only b, only c, both (e.g., simultaneously) a and b, both (e.g., simultaneously) a and c, both (e.g., simultaneously) b and c, all of a, b, and c, or variations thereof.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within +30%, +20%, +10%, or +5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

In the present disclosure, it will be understood that if (e.g., when) an element (e.g., a region, a layer, a portion, and/or the like) is referred to as being “on,” “connected to,” or “coupled to” another element, it may be directly on, directly connected to, or directly coupled to the other element, or intervening elements may be present therebetween. In contrast, if (e.g., when) an element is referred to as being “directly on,” “directly connected to,” or “directly coupled to” another element, there are no intervening elements present therebetween.

In the drawings, the thicknesses, ratios, and dimensions of elements may be exaggerated to effectively or suitably illustrate the technical contents.

It will be understood that, although the terms “first,” “second,” and/or the like may be used herein to describe one or more suitable elements, these elements should not be limited by these terms. These terms are only used to distinguish one element from another element. For example, a first element may be termed a second element without departing from the scope of the present disclosure. Similarly, the second element may also be referred to as the first element.

In the present disclosure, the terms, such as “below,” “lower,” “above,” “upper,” and/or the like, are used herein for ease of description to describe one element's relation to another element(s) as illustrated in the drawings. The foregoing terms are relative concepts and are described based on the directions indicated in the drawings.

It will be understood that the terms “includes,” “including,” “has,” and/or “having,” if (e.g., when) used in the present disclosure, specify the presence of stated features, integers, steps, operations, elements, components, and/or groups thereof, but do not preclude the presence or addition of one or more other features, integers, steps, operations, elements, components, and/or groups thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

The term “part” or “unit” refers to a software component or hardware component that performs a specific (e.g., set or predetermined) function. The hardware component may include, for example, a field-programmable gate array (FPGA) or an application-specific integrated circuit (ASIC). The software component may refer to an executable code and/or data used by the executable code in an addressable storage medium. Accordingly, the software components may be, for example, object-oriented software components, class components, and task components, and may include processes, functions, attributes, procedures, subroutines, program code segments, drivers. firmware, micro codes, circuits, data, databases, data structures, tables, arrays, and/or variables.

Unless otherwise defined, all terms (including technical and scientific terms) used herein have substantially the same meaning as generally understood by one of ordinary skill in the art to which this disclosure belongs. It will be further understood that terms, such as those defined in generally used dictionaries, should be interpreted as having a meaning that is consistent with their meaning in the context of the relevant art and will not be interpreted in an idealized or overly formal sense unless expressly so defined herein.

Hereinafter, one or more embodiments of the present disclosure will be described in more detail with reference to the drawings.

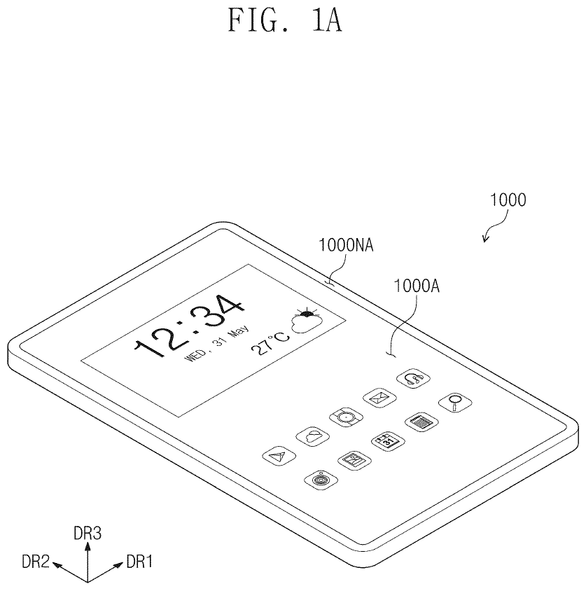

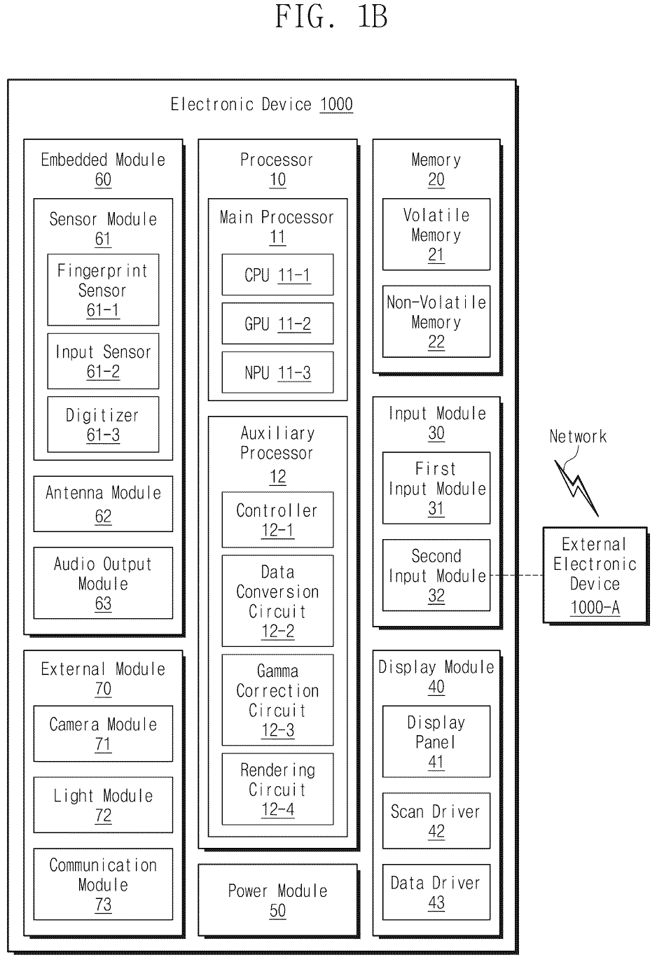

FIG. 1A is a perspective view of an electronic device according to one or more embodiments. FIG. 1B is a block diagram of the electronic device according to one or more embodiments. One or more embodiments of the present disclosure will be described in more detail with reference to FIGS. 1A and 1B.

Referring to FIG. 1A, the electronic device 1000 may be activated by an electrical signal. For example, the electronic device 1000 may be a mobile phone, a foldable mobile phone, a laptop computer, a television, a tablet, a car navigation system, a game console, or a wearable device, but embodiments of the present disclosure are not limited thereto. The wearable device may be a device worn on a user's body and include a head-mounted display (HMD) that implements extended reality (XR). For example, FIG. 1A illustrates that the electronic device 1000 is a mobile phone.

An active region 1000A and a peripheral region 1000NA may be defined in the electronic device 1000. The electronic device 1000 may display an image through the active region 1000A. The active region 1000A may include a surface defined by a first direction DR1 and a second direction DR2. The peripheral region 1000NA may be around (e.g., surround) the periphery of the active region 1000A. In one or more embodiments, the peripheral region 1000NA may not be provided.

The thickness direction of the electronic device 1000 may be parallel (e.g., substantially parallel) to a third direction DR3 crossing the first direction DR1 and the second direction DR2. Accordingly, the front (or upper) and rear (or lower) surfaces of the components constituting the electronic device 1000 may be defined based on the third direction DR3.

Referring to FIG. 1B, the electronic device 1000 may output one or more suitable information through a display module 40 within an operating system. If (e.g., when) a processor 10 executes an application stored in a memory 20, the display module 40 may provide application information to a user through a display panel 41.

The processor 10 may obtain an external input through an input module 30 or a sensor module 61 and execute an application corresponding to the external input. For example, if (e.g., when) a user selects a camera icon displayed on the display panel 41, the processor 10 may obtain a user input through an input sensor 61-2 and activate a camera module 71. The processor 10 may transmit image data, which correspond to a captured image obtained through the camera module 71, to the display module 40. The display module 40 may display an image corresponding to the captured image through the display panel 41.

In one or more embodiments, the operation of the electronic device 1000 has been briefly described. Hereafter, the configuration or arrangement of the electronic device 1000 will be described in more detail. One or more of the components of the electronic device 1000 as described herein may be provided as one integrated component, and one component may be provided by being separated into two or more components.

Referring to FIG. 1B, the electronic device 1000 may communicate with an external electronic device 1000-A through a network (e.g., a short-range wireless communication network or a long-range wireless communication network). According to one or more embodiments, the electronic device 1000 may include a processor 10, a memory 20, an input module 30, a display module 40, a power module 50, a built-in module 60, and an external module 70. According to one or more embodiments, at least one selected from among the components of the electronic device 1000 as described in one or more embodiments may not be provided, or one or more other components may be added. According to one or more embodiments, one or more (e.g., the sensor module 61, an antenna module 62, and/or an audio output module 63) of the components as described in one or more embodiments may be integrated into another component (e.g., the display module 40).

The processor 10 may execute software to control at least one other component (e.g., a hardware component or a software component) of the electronic device 1000, which is connected to the processor 10 and perform one or more suitable data processing or operations. According to one or more embodiments, as at least part of the data processing or operations, the processor 10 may store commands or data received from other components (e.g., the input module 30, the sensor module 61, or a communication module 73) in volatile memory 21, process the commands or data stored in the volatile memory 21, and store resulting data in non-volatile memory 22.

The processor 10 may include a main processor 11 and an auxiliary processor 12. The main processor 11 may include one or more of a central processing unit (CPU) 11-1 or an application processor (AP). The main processor 11 may further include one or more selected from among a graphic processing unit (GPU) 11-2, a communication processor (CP), and an image signal processor (ISP). The main processor 11 may further include a neural network processing unit (NPU) 11-3. The neural network processing unit may be a processor specialized in processing an artificial intelligence model, and the artificial intelligence model may be generated through machine learning. The artificial intelligence model may include a plurality of artificial neural network layers. An artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-networks, or a combination of two or more selected from among the foregoing networks, but embodiments of the present disclosure are not limited to the examples described herein. The artificial intelligence model may additionally or alternatively include software structures in addition to hardware structures. At least two selected from among the processing units and processors as described herein may be implemented as a single integrated component (e.g., a single chip), or each thereof may be implemented as an independent component (e.g., a plurality of chips).

The auxiliary processor 12 may include a controller 12-1. The controller 12-1 may include an interface conversion circuit and a timing control circuit. The controller 12-1 may receive an image signal from the main processor 11, convert the data format of the image signal to match the interface specifications of the display module 40, and output image data. The controller 12-1 may output one or more suitable control signals necessary or desired to drive the display module 40.

The auxiliary processor 12 may further include a data conversion circuit 12-2, a gamma correction circuit 12-3, a rendering circuit 12-4, and/or the like. The data conversion circuit 12-2 may receive image data from the controller 12-1 and compensate for the image data so that (e.g., such that) an image is displayed at a desired brightness according to the characteristics of the electronic device 1000 or user settings, or convert the image data to reduce power consumption or compensate for afterimages, and/or the like. The gamma correction circuit 12-3 may convert image data, a gamma reference voltage and/or the like so that (e.g., such that) the image displayed on the electronic device 1000 has desired gamma characteristics. The rendering circuit 12-4 may receive image data from the controller 12-1 and render the image data by considering the pixel arrangement and/or the like of the display panel 41, which is applied to the electronic device 1000. At least one of the data conversion circuit 12-2, the gamma correction circuit 12-3, or the rendering circuit 12-4 may be integrated into another component (e.g., the main processor 11 or the controller 12-1). At least one of the data conversion circuit 12-2, the gamma correction circuit 12-3, or the rendering circuit 12-4 may also be integrated into a data driver 43 to be described herein in more detail.

The memory 20 may store one or more suitable data used by at least one component (e.g., the processor 10 or the sensor module 61) of the electronic device 1000 and input data or output data for commands related thereto. The memory 20 may include at least one of volatile memory 21 or non-volatile memory 22.

The input module 30 may receive commands or data, which are used for components (e.g., the processor 10, the sensor module 61, or the audio output module 63) of the electronic device 1000, from the outside of the electronic device 1000 (e.g., a user or the external electronic device 1000-A).

The input module 30 may include a first input module 31 into which commands or data are input from a user and a second input module 32 into which commands or data are input from the external electronic device 1000-A. The first input module 31 may include a microphone, a mouse, a keyboard, a key (e.g., a button), and/or a pen (e.g., a passive pen or an active pen). The second input module 32 may support a designated protocol that connects the second input module 32 to the external electronic device 1000-A by wire or wirelessly. According to one or more embodiments, the second input module 32 may include a high definition multimedia interface (HDMI), a universal serial bus (USB) interface, an SD card interface, and/or an audio interface. The second input module 32 may include a connector, which physically connects the second input module 32 to the external electronic device 1000-A, such as an HDMI connector, a USB connector, an SD card connector, or an audio connector (e.g., a headphone connector).

The display module 40 may visually provide information to a user. The display module 40 may include a display panel 41, a scan driver 42, and a data driver 43. The display module 40 may further include a chassis, a bracket, and a window to protect the display panel 41.

The display panel 41 may include a liquid crystal display panel, an organic light-emitting display panel, or an inorganic light-emitting display panel, and the type or kind of the display panel 41 is not particularly limited thereto. The display panel 41 may be a rigid type or kind or a flexible type or kind that may be rolled or folded. The display module 40 may further include a heat dissipation member, a bracket, and/or a supporter that supports the display panel 41.

The scan driver 42 may be mounted on the display panel 41 as a driving chip. In one or more embodiments, the scan driver 42 may be integrated into the display panel 41. For example, the scan driver 42 may include an amorphous (e.g., non-crystalline) silicon TFT gate driver circuit (ASG), a low temperature polycrystalline silicon (LTPS) TFT gate driver circuit, and/or an oxide semiconductor TFT gate driver circuit (OSG) embedded in the display panel 41. The scan driver 42 may receive a control signal from the controller 12-1 and output scan signals to the display panel 41 in response to the control signal.

The display panel 41 may further include a light-emitting driver. The light-emitting driver may output a light-emitting control signal to the display panel 41 in response to the control signal received from the controller 12-1. The light-emitting driver may be formed or provided separately from or integrated into the scan driver 42.

The data driver 43 may receive a control signal from the controller 12-1, convert image data into an analog voltage (e.g., a data voltage) in response to the control signal, and then output data voltages to the display panel 41.

The data driver 43 may be integrated into another component (e.g., the controller 12-1). The functions of the interface conversion circuit and the timing control circuit of the controller 12-1 as described in one or more embodiments may also be integrated into the data driver 43.

The display module 40 may further include a light-emitting driver, a voltage generation circuit, and/or the like. The voltage generation circuit may output one or more suitable voltages required or desired to drive the display panel 41.

The power module 50 may supply power to the components of the electronic device 1000. The power module 50 may include a battery that charges a power voltage. The battery may include a non-rechargeable primary battery, a rechargeable secondary battery, or a fuel cell. The power module 50 may include a power management integrated circuit (PMIC). The PMIC may supply power optimized for each of the modules as described in one or more embodiments and modules to be described herein. The power module 50 may include a wireless power transmission/reception member electrically connected to the battery. The wireless power transmission/reception member may include a plurality of coil-shaped antenna radiators.

The electronic device 1000 may further include a built-in module 60 and an external module 70. The built-in module 60 may include a sensor module 61, an antenna module 62, and an audio output module 63. The external module 70 may include a camera module 71, a light module 72, and a communication module 73.

The sensor module 61 may sense an input by a body part of a user or an input by a pen among the first input modules 31 and generate an electric signal or a data value corresponding to the input. The sensor module 61 may include at least any one of a fingerprint sensor 61-1, an input sensor 61-2, or a digitizer 61-3.

The fingerprint sensor 61-1 may generate a data value corresponding to a user's fingerprint. The fingerprint sensor 61-1 may include either an optical fingerprint sensor or a capacitive fingerprint sensor.

The input sensor 61-2 may generate a data value corresponding to the coordinate information of an input by a body part of a user or an input by a pen. The input sensor 61-2 may generate the data value based on the amount of change in capacitance caused by an input. The input sensor 61-2 may sense an input by a passive pen or transmit/receive data to/from an active pen.

The input sensor 61-2 may also measure a biometric signal, such as blood pressure, hydration levels, or body fat. For example, if (e.g., when) a user touches a sensor layer or a sensing panel using a part of his/her body and does not move for a certain (e.g., set or predetermined) period of time, the input sensor 61-2 may sense a biometric signal based on changes in an electric field caused by the part of his/her body and output information desired by the user to the display module 40.

The digitizer 61-3 may generate a data value corresponding to the coordinate information of an input by a pen. The digitizer 61-3 may generate the data value based on the amount of change in electromagnetic force caused by the input. The digitizer 61-3 may sense an input by a passive pen or transmit/receive data to/from an active pen.

At least one of the fingerprint sensor 61-1, the input sensor 61-2, or the digitizer 61-3 may be implemented as a sensor layer formed or provided on the display panel 41 through a continuous process. The fingerprint sensor 61-1, the input sensor 61-2, and the digitizer 61-3 may be disposed or provided on the upper side of the display panel 41, and any one selected from among the fingerprint sensor 61-1, the input sensor 61-2, and the digitizer 61-3, for example, the digitizer 61-3 may be disposed or provided on the lower side of the display panel 41.

At least two of the fingerprint sensor 61-1, the input sensor 61-2, or the digitizer 61-3 may be formed or provided to be integrated into one sensing panel through substantially the same process. If (e.g., when) integrated into one sensing panel, the sensing panel may be disposed or provided between the display panel 41 and the window disposed or provided on the upper side of the display panel 41. According to one or more embodiments, the sensing panel may be disposed or provided on the window, and the position of the sensing panel is not particularly limited.

At least one of the fingerprint sensor 61-1, the input sensor 61-2, or the digitizer 61-3 may be built into the display panel 41. For example, at least one of the fingerprint sensor 61-1, the input sensor 61-2, or the digitizer 61-3 may be formed or provided concurrently (e.g., simultaneously) through a process to form or provide the elements (e.g., light-emitting elements, transistors, and/or the like) included in the display panel 41.

In one or more embodiments, the sensor module 61 may generate an electric signal or a data value corresponding to an internal or external state of the electronic device 1000. The sensor module 61 may further include, for example, a gesture sensor, a gyro sensor, a pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The antenna module 62 may include one or more antennas to transmit or receive signals or power to or from the outside. According to one or more embodiments, the communication module 73 may transmit signals to or receive signals from an external electronic device through an antenna suitable for a communication method. The antenna pattern of the antenna module 62 may be integrated into one component (e.g., the display panel 41) of the display module 40, the input sensor 61-2, and/or the like.

The audio output module 63 may be a device to output audio signals to the outside of the electronic device 1000 and may include, for example, a speaker used for general purposes, such as multimedia playback or recording playback, and a receiver used exclusively for phone reception. According to one or more embodiments, the receiver may be formed or provided integrally with or separately from the speaker. The audio output pattern of the audio output module 63 may be integrated into the display module 40.

The camera module 71 may capture still images and/or moving images. According to one or more embodiments, the camera module 71 may include one or more lenses, an image sensor, or an image signal processor. The camera module 71 may further include an infrared camera capable of measuring the presence, position, gaze, and/or the like of a user.

The light module 72 may provide light. The light module 72 may include a light-emitting diode or a xenon lamp. The light module 72 may operate in conjunction with the camera module 71 or independently.

The communication module 73 may support the establishment of a wired communication channel or a wireless communication channel between the electronic device 1000 and the external electronic device 1000-A and the performance of communication through the established communication channel. The communication module 73 may include any one or all of a wireless communication module, such as a cellular communication module, a short-range wireless communication module, or a global navigation satellite system (GNSS) communication module and a wired communication module, such as a local area network (LAN) communication module or a power line communication module. The communication module 73 may communicate with the external electronic device 1000-A via a short-range communication network, such as Bluetooth, WiFi direct, or infrared data association (IrDA), or a long-range communication network, such as a cellular network, the internet, or a computer network (e.g., LAN or WAN). The one or more suitable types or kinds of communication modules 73 as described herein may be implemented as one chip, or each type or kind may be implemented as a separate chip.

The input module 30, the sensor module 61, the camera module 71, and/or the like may be utilized to control the operation of the display module 40 in conjunction with the processor 10.

The processor 10 may output commands or data to the display module 40, the audio output module 63, the camera module 71, or the light module 72, based on input data received from the input module 30. For example, the processor 10 may generate image data in response to input data applied by a mouse, an active pen, and/or the like and output the image data to the display module 40, or generate command data in response to the input data and output the image data to the camera module 71 or the light module 72. If (e.g., when) no input data is received from the input module 30 for a certain (e.g., set or predetermined) period of time, the processor 10 may convert the operation mode of the electronic device 1000 into a low power mode or a sleep mode to reduce the power consumption of the electronic device 1000.

The processor 10 may output commands or data to the display module 40, the audio output module 63, the camera module 71, or the light module 72, based on sensing data received from the sensor module 61. For example, the processor 10 may compare authentication data applied from the fingerprint sensor 61-1 with authentication data stored in the memory 20 and then execute an application, based on the comparison result. Based on the sensing data sensed by the input sensor 61-2 or the digitizer 61-3, the processor 10 may execute commands or output corresponding image data to the display module 40. If (e.g., when) the sensor module 61 includes a temperature sensor, the processor 10 may receive temperature data on a temperature measured from the sensor module 61 and may further perform brightness correction and/or the like on image data, based on the temperature data.

The processor 10 may receive measurement data on the presence or absence of a user, the position of the user, the line of sight of the user, and/or the like from the camera module 71. The processor 10 may further perform brightness correction and/or the like on image data, based on the measurement data. For example, the processor 10 that has determined the presence or absence of a user through an input from the camera module 71 may output image data, whose brightness has been corrected through the data conversion circuit 12-2 or the gamma correction circuit 12-3, to the display module 40.

One or more of the foregoing components may be connected to each other through a communication method between peripheral devices, such as a bus, a general purpose input/output (GPIO), a serial peripheral interface (SPI), a mobile industry processor interface (MIPI), or an Ultra Path Interconnect (UPI) link, and may exchange signals (e.g., commands or data) with each other. The processor 10 may communicate with the display module 40 through a mutually agreed upon interface and may use, for example, any one selected from among the communication methods as described herein, and embodiments of the present disclosure are not limited to the communication methods as described herein.

The electronic device 1000 according to one or more embodiments of the present disclosure may take one or more suitable forms. The electronic device 1000 may include, for example, at least one of a portable communication device (e.g., a smart phone), a computer device, a portable multimedia device, a portable medical device, a camera, a wearable device, or an electric home appliance. The electronic device 1000 according to one or more embodiments of the present disclosure is not limited to the devices as described herein.

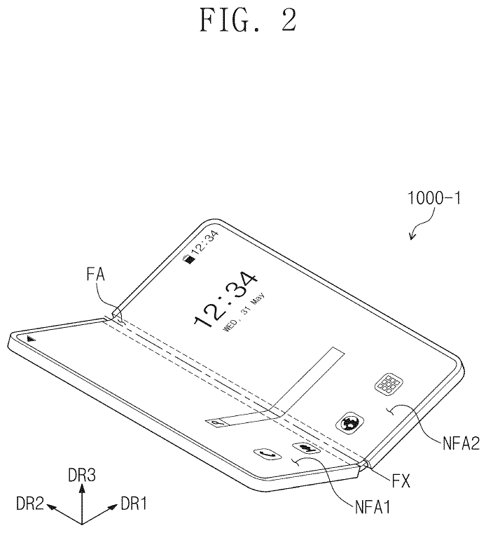

FIG. 2 is a perspective view of an electronic device 1000-1 according to one or more embodiments.

Referring to FIG. 2, the electronic device 1000-1 may include a folding region FA and a plurality of non-folding regions NFA1 and NFA2. The non-folding regions NFA1 and NFA2 may include a first non-folding region NFA1 and a second non-folding region NFA2. The folding region FA may be disposed or provided between the first non-folding region NFA1 and the second non-folding region NFA2. The folding region FA may be referred to as a foldable region, and the first and second non-folding regions NFA1 and NFA2 may be referred to as first and second non-foldable regions.

As illustrated in FIG. 2, the folding region FA may be folded based on a folding axis FX parallel (e.g., substantially parallel) to the second direction DR2. If (e.g., when) the electronic device 1000-1 is folded, the folding region FA may have a set or predetermined curvature and a set or predetermined curvature radius. The first non-folding region NFA1 and the second non-folding region NFA2 may be opposite to (e.g., face) each other, and the electronic device 1000-1 may be inner-folded so that (e.g., such that) a display surface DS is not exposed to the outside.

In one or more embodiments, the electronic device 1000-1 may be outer-folded so that (e.g., such that) the display surface DS is exposed to the outside. In one or more embodiments, the electronic device 1000-1 may be inner-folded or outer-folded in an unfolded state, but embodiments of the present disclosure are not limited thereto.

FIG. 2 illustrates that one folding axis FX is defined in the electronic device 1000-1, but embodiments of the present disclosure are not limited thereto. For example, a plurality of folding axes may be defined in the electronic device 1000-1, and the electronic device 1000-1 may be inner-folded or outer-folded in an unfolded state at each of the plurality of folding axes.

FIGS. 1A and 2 illustrate a bar-type or kind electronic device 1000 and a foldable-type or kind electronic device 1000-1, respectively, but embodiments of the present disclosure are not limited thereto. For example, the descriptions provided herein may be applied to one or more suitable electronic devices, such as a curved electronic device, a rollable electronic device, or a slidable electronic device.

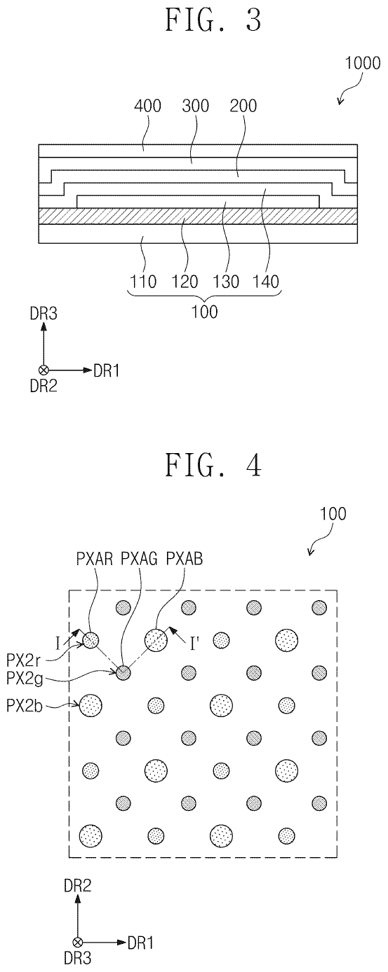

FIG. 3 is a cross-sectional view of a display device according to one or more embodiments. Hereinafter, one or more embodiments of the present disclosure will be described in more detail with reference to FIG. 3.

In one or more embodiments, the electronic device 1000 may include a display device DD, a first electronic module EM1, a second electronic module EM2, a power supply module PM, and housings EDC1 and EDC2. The electronic device 1000 may further include a mechanical structure to control the folding operation of the display device DD.

The display device DD may include a window WN and an electronic panel EP. The window WN may cover the upper surface of the electronic panel EP and provide the front surface of the electronic device 1000.

In one or more embodiments, the electronic panel EP and the window member WN may be configured or provided in the display device DD. In one or more embodiments, the display device DD may be substantially a stacked structure in which a plurality of components including the electronic panel EP are stacked. For example, the display device DD may further include at least one component, such as a support plate or a shock absorbing layer, disposed or provided on the rear surface of the electronic panel EP.

For example, referring to FIG. 3, the display device DD may include a display layer 100, a sensor layer 200, an optical layer 300, and a window 400. In one or more embodiments, the window 400 may correspond to the window member WN as described in one or more embodiments, and the display layer 100, the sensor layer 200, and the optical layer 300 may correspond to the electronic panel EP. However, this is only an example, and the display device DD may not include the optical layer 300 and the window 400.

The display layer 100 may correspond to the display panel 41 as described in one or more embodiments (see FIG. 1B). The display layer 100 may include a base layer 110, a circuit layer 120, an element layer 130, and an encapsulation layer 140.

The base layer 110 may be a member that provides a base surface on which the circuit layer 120 is disposed or provided. The base layer 110 may be a glass substrate, a metal substrate, a silicon substrate, a polymer substrate, and/or the like. However, embodiments of the present disclosure are not limited thereto, and the base layer 110 may be an inorganic layer, an organic layer, or a composite material layer.

The circuit layer 120 may be disposed or provided on the base layer 110. The circuit layer 120 may include an insulating (e.g., electrically insulating) layer, a semiconductor pattern, a conductive (e.g., electrically conductive) pattern, a signal line, and/or the like. An insulating (e.g., electrically insulating) layer, a semiconductor layer, and a conductive (e.g., electrically conductive) layer may be formed or provided on the base layer 110 by a method, such as coating and deposition, and then the insulating layer, the semiconductor layer, and the conductive layer may be selectively patterned through a plurality of photolithography processes. Hereafter, the semiconductor pattern, the conductive pattern, and the signal line included in the circuit layer 120 may be formed or provided.

The element layer 130 may be disposed or provided on the circuit layer 120. The element layer 130 may include a light-emitting element. For example, the element layer 130 may include an organic light-emitting material, an inorganic light-emitting material, an organic-inorganic light-emitting material, a quantum dot, a quantum rod, a micro LED, or a nano LED.

The encapsulation layer 140 may be disposed or provided on the element layer 130. The encapsulation layer 140 may protect the element layer 130 from moisture, oxygen, and/or foreign substances, such as dust particles.

The sensor layer 200 may be disposed or provided on the display layer 100. The sensor layer 200 may correspond to the sensor module 61 (see FIG. 1B) as described in one or more embodiments. For example, the sensor layer 200 may include the input sensor 161-2 (see FIG. 1B), but embodiments of the present disclosure are not limited thereto and may include at least any one of the fingerprint sensor 61-1 (see FIG. 1B), the input sensor 61-2, or the digitizer 61-3 (see FIG. 1B), and embodiments of the present disclosure are not limited to any one embodiment. The sensor layer 200 may be formed or provided on the display layer 100 through a continuous process. In this case, the sensor layer 200 may be expressed as being directly disposed or provided on the display layer 100. Being directly disposed or provided may refer to that a third component is not disposed or provided between the sensor layer 200 and the display layer 100. For example, a separate adhesive member may not be disposed or provided between the sensor layer 200 and the display layer 100. In one or more embodiments, the sensor layer 200 may be coupled to the display layer 100 by an adhesive member. The adhesive member may include an adhesive and/or a glue that are generally available or generally used.

The optical layer 300 may be disposed or provided on the sensor layer 200. The optical layer 300 may reduce the reflectance of external light incident from the outside of the electronic device 1000. The optical layer 300 may be directly disposed or provided on the sensor layer 200. Without being limited thereto, however, an adhesive member may be disposed or provided between the optical layer 300 and the sensor layer 200.

The window 400 may be disposed or provided on the optical layer 300. An adhesive member may be disposed or provided between the optical layer 300 and the window 400, but embodiments of the present disclosure are not particularly limited thereto. The window 400 may include an optically transparent (e.g., substantially transparent) insulating (e.g., electrically insulating) material. For example, the window 400 may include glass and/or plastic. The window 400 may have a multi-layer structure or a single-layer structure. For example, the window 400 may include a plurality of plastic films bonded to each other with an adhesive or may include a glass substrate and a plastic film bonded to each other with an adhesive.

In one or more embodiments, a display region DA of the electronic panel EP may include a first region A1 and a second region A2. In one or more embodiments, the first region A1 may have a circular shape (e.g., a substantially circular shape), but may have one or more suitable shapes, such as a polygon (e.g., a substantially polygon), an ellipse (e.g., a substantially ellipse), a figure having at least one curved side or an irregular shape, and embodiments of the present disclosure are not limited thereto. The first region A1 may be referred to as a component region, and the second region A2 may be referred to as a main display region or a general display region.

For example, the first region A1 may have a higher transmittance than the second region A2. In one or more embodiments, the resolution of the first region A1 may be lower than the resolution of the second region A2, but embodiments of the present disclosure are not limited thereto. For example, the first region A1 may have a higher transmittance than the second region A2, but the resolution of the first region A1 may be substantially the same as the resolution of the second region A2. The first region A1 may overlap a camera module CMM. The camera module CMM may be corresponding to the camera module 71 as illustrated at FIG. 1B. In one or more embodiments, a portion of the electronic panel EP corresponding to the first region A1 may be removed. Accordingly, an image may not be displayed on the first region A1. In one or more embodiments, the electronic panel EP may correspond to the display layer 100, the sensor layer 200, and the optical layer 300 of FIG. 3, but this is illustrated as an example, and in the electronic panel EP, the sensor layer 200 or the optical layer 300 may not be provided, and embodiments of the present disclosure are not limited thereto.

A driving unit DIC and a circuit board FCB may include driving elements to drive pixels of the display layer 100. The driving unit DIC may include, for example, a gate driving circuit or a data driving circuit, and the circuit board FCB may include, for example, a timing control circuit or a power supply circuit. In one or more embodiments, the driving unit DIC and the circuit board FCB may include driving elements to drive the sensor layer 200. However, this is described as an example, and the driving elements to drive the sensor layer 200 may be provided on a substrate separate from the driving unit DIC or the circuit board FCB, and embodiments of the present disclosure are not limited thereto.

The driving unit DIC may be disposed or provided in a non-display region NDA. However, this is illustrated as an example, and the driving unit DIC may be disposed or provided in the display region DA, and the arrangement position of the driving unit DIC is not limited thereto. In one or more embodiments, the driving unit DIC may be mounted on the electronic panel EP in the form of a chip, but embodiments of the present disclosure are not limited thereto. For example, the driving unit DIC may be mounted on the circuit board FCB and connected to the electronic panel EP through the circuit board FCB.

The power supply module PM may supply power required or desired for the overall operation of the electronic device 1000. The power supply module PM may correspond to the power module 50 as described in one or more embodiments or may form a portion of the power module 50. The power supply module PM may include a battery module that is generally available. In one or more embodiments, the circuit board FCB may be connected to the power supply module PM to receive power, and power required or desired for the electronic panel EP or the driving unit DIC may be supplied through the circuit board FCB.

The first electronic module EM1 and the second electronic module EM2 may include one or more suitable functional modules to operate the electronic device 1000. Each of the first electronic module EM1 and the second electronic module EM2 may be directly mounted on a motherboard electrically connected to the electronic panel EP or may be mounted on a separate board and electrically connected to the motherboard through a connector and/or the like. The motherboard may be provided separately or may correspond to the circuit board FCB. Each of the first electronic module EM1 and the second electronic module EM2 may include at least one of a processor 10, a memory 20, an input module 30, or an external module 70.

The first electronic module EM1 may include a control module CM, a wireless communication module TM, an image input module IIM, an audio input module AIM, a memory MM, and an external interface IF.

The control module CM may control the overall operation of the electronic device 1000. The control module CM may be a microprocessor. For example, the control module CM may activate or deactivate the electronic panel EP. The control module CM may control other modules, such as the image input module IIM or the audio input module AIM, based on a touch signal received from the electronic panel EP.

The wireless communication module TM may communicate with an external electronic device via a first network (e.g., a short-range communication network, such as Bluetooth, WiFi direct, or infrared data association (IrDA)) or a second network (e.g., a long-range communication network, such as a cellular network, the Internet, or a computer network (e.g., LAN or WAN)). The communication modules included in the wireless communication module TM may be integrated into a single component (e.g., a single chip) or implemented as a plurality of separate components (e.g., a plurality of chips). The wireless communication module TM may transmit/receive a voice signal using a general communication line. The wireless communication module TM may include a transmitter TM1 that modulates and transmits a signal to be transmitted and a receiver TM2 that demodulates a received signal.

The image input module IIM may process an image signal and convert it into image data that may be displayed on the electronic panel EP. The audio input module AIM may receive an external audio signal from a microphone in recording mode, voice recognition mode, and/or the like and convert it into electrical voice data.

The external interface IF may include a connector that may physically connect the electronic device 1000 and the external electronic device to each other. For example, the external interface IF may function as an interface connecting the electronic device 1000 to an external charger, a wired/wireless data port, a card (e.g., a memory card, a SIM/UIM card, and/or the like) socket, and/or the like.

The second electronic module EM2 may include an audio output module AOM, a light-emitting module LTM, a light-receiving module LRM, and a camera module CMM. The audio output module AOM may convert audio data received from the wireless communication module TM or audio data stored in the memory MM and output them to the outside.

The light-emitting module LTM may generate and output light. The light-emitting module LTM may output infrared light. The light-emitting module LTM may include an LED element. The light-receiving module LRM may sense infrared light. The light-receiving module LRM may be activated if (e.g., when) infrared light above a set or predetermined level is sensed. The light-receiving module LRM may include a complementary metal oxide semiconductor (CMOS) sensor. After infrared light generated from the light-emitting module LTM is output, the infrared light may be reflected by an external object (e.g., a user's finger or face), and the reflected infrared light may be incident on the light-receiving module LRM.

The camera module CMM may capture still images and moving images. The camera module CMM may be provided in plurality. One or more of the camera modules CMM may overlap the first region A1. An external input (e.g., light) may be provided to the camera module CMM through the first region A1. For example, the camera module CMM may receive natural light through the first region A1 to capture an external image.

The housings EDC1 and EDC2 may provide an accommodation space. The accommodation space may accommodate the display device DD, the first and second electronic modules EM1 and EM2, and the power supply module PM. The housings EDC1 and EDC2 may protect the components accommodated in the accommodation space. In one or more embodiments, two housings EDC1 and EDC2 may be separated from each other, but embodiments of the present disclosure are not limited thereto. In one or more embodiments, in addition to the two housings EDC1 and EDC2, the electronic device 1000 may further include a hinge unit connecting them to each other. The housings EDC1 and EDC2 may be connected to the hinge unit to easily perform a folding operation. The electronic device 1000 according to one or more embodiments may include one or more suitable other components in addition to this, and any illustrated component may not be provided, and embodiments of the present disclosure are not limited thereto.

FIG. 4 is an enlarged plan view illustrating a partial region of a display layer according to one or more embodiments. Referring to FIG. 4, the display layer 100 may include a plurality of pixels PXr, PXg, and PXb. The pixels PXr, PXg, and PXb may include a first pixel PXr, a second pixel PXg, and a third pixel PXb.

A first light-emitting region PXAR may be defined in the first pixel PXr, a second light-emitting region PXAG may be defined in the second pixel PXg, and a third light-emitting region PXAB may be defined in the third pixel PXb. Circular shapes (e.g., substantially circular shapes) as illustrated in FIG. 4 may correspond to the shapes of the first to third light-emitting regions PXAR, PXAG, and PXAB, respectively. However, the shape of each of the first to third light-emitting regions PXAR, PXAG, and PXAB is not limited thereto. For example, the first to third light-emitting regions PXAR, PXAG, and PXAB may have one or more suitable shapes, such as tetragonal (e.g., substantially tetragonal), polygonal (e.g., substantially polygonal), elliptical (e.g., substantially elliptical), triangular (e.g., substantially triangular), or atypical shapes, on a plane.

In one or more embodiments, the first pixel PXr and the third pixel PXb may be arranged alternately and repeatedly one by one in each of the first direction DR1 and the second direction DR2. The second pixel PXg may be arranged in a space between two diagonally adjacent first pixels PXr and two diagonally adjacent third pixels PXb. However, the arrangement relationship of the first to third pixels PXr, PXg, and PXb as illustrated in FIG. 4 is an example, and the arrangement relationship of the first to third pixels PXr, PXg, and PXb is not particularly limited thereto. The diagonal direction as described herein may be a direction between the first direction DR1 and the second direction DR2 or between a direction opposite to the first direction DR1 and the second direction DR2.

In one or more embodiments, the area of the third light-emitting region PXAB may be the largest, and the area of the second light-emitting region PXAG may be the smallest. However, embodiments of the present disclosure are not limited thereto. For example, the areas of the first to third light-emitting regions PXAR, PXAG, and PXAB may be substantially the same as each other or may be different from the illustrated examples.

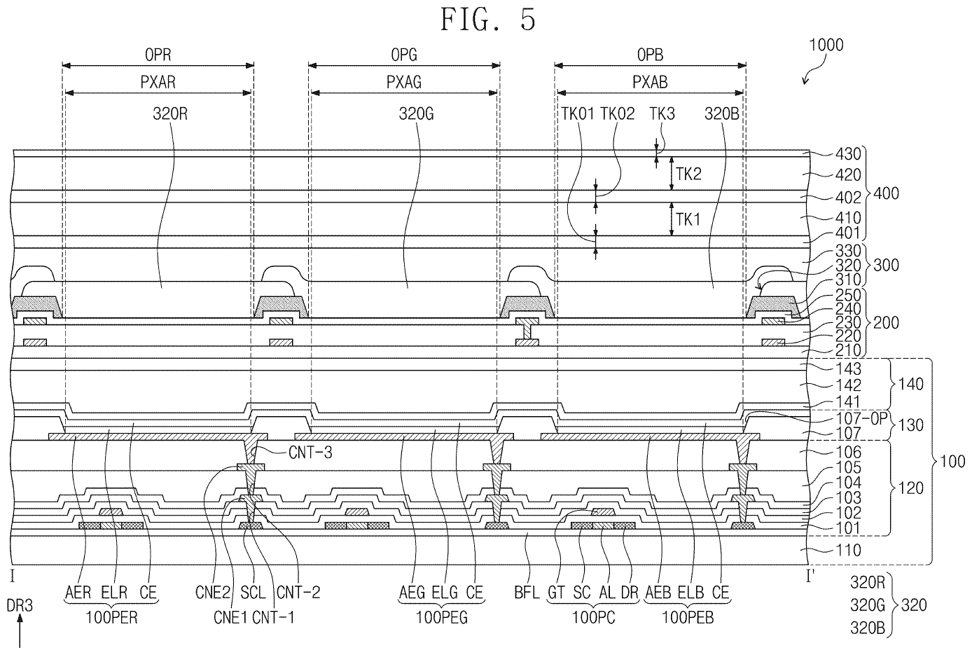

FIG. 5 is a cross-sectional view illustrating a portion of an electronic device according to one or more embodiments. For example, FIG. 5 is a cross-sectional view which includes a display layer according to one or more embodiments and is taken along the line I-I′ as illustrated in FIG. 4.

Referring to FIG. 5, at least one inorganic layer may be disposed or provided on the upper surface of the base layer 110. The inorganic layer may include at least one of aluminum oxide, titanium oxide, silicon oxide, silicon nitride, silicon oxynitride, zirconium oxide, or hafnium oxide. The inorganic layer may be formed or provided as a plurality of layers. The multi-layer inorganic layers may constitute a barrier layer and/or a buffer layer. In one or more embodiments, the display layer 100 may be illustrated as including a buffer layer BFL as an inorganic layer.

The buffer layer BFL may improve or enhance bonding strength between the base layer 110 and the semiconductor pattern. The buffer layer BFL may include at least one of silicon oxide, silicon nitride, or silicon oxynitride. For example, the buffer layer BFL may include a structure in which silicon oxide layers and silicon nitride layers are alternately stacked.

The semiconductor pattern may be disposed or provided on the buffer layer BFL. The semiconductor pattern may include polysilicon. Without being limited thereto, however, the semiconductor pattern may include amorphous (e.g., non-crystalline) silicon, low-temperature polycrystalline silicon, and/or oxide semiconductor.

FIG. 5 merely illustrates one or more of the semiconductor patterns, and additional semiconductor patterns may be disposed or provided in other regions. The semiconductor patterns may be disposed or provided in a specific (e.g., set or predetermined) rule across the pixels. The semiconductor patterns may have different electrical properties depending on whether they are doped or not. The semiconductor pattern may include a first region having high conductivity (e.g., electrical conductivity) and a second region having low conductivity (e.g., electrical conductivity). The first region may be doped with a negative type or kind (N-type or kind) dopant or a positive type or kind (P-type or kind) dopant. A P-type or kind transistor may include a doped region doped with a P-type or kind dopant, and an N-type or kind transistor may include a doped region doped with an N-type or kind dopant. The second region may be an undoped region or a region doped at a lower concentration than the first region.

The conductivity of the first region may be greater than the conductivity of the second region, and the first region may substantially function as an electrode or a signal line. The second region may substantially correspond to an active region (or channel) of a transistor. For example, a portion of the semiconductor pattern may be an active region of a transistor, another portion thereof may be a source or drain of a transistor, and still another portion thereof may be a connection electrode or a connection signal line.

Each of the pixels may include a pixel circuit and a light-emitting element. The pixel circuit may include a plurality of transistors and at least one capacitor. FIG. 5 illustrates a transistor 100PC and a light-emitting element 100PER, 100PEG, or 100PEB included in each of three pixels.

A source region SC, an active region AL, and a drain region DR of the transistor 100PC may be formed or provided from a semiconductor pattern. The source region SC and the drain region DR may extend in opposite directions from each other from the active region AL on a cross section. FIG. 5 illustrates a portion of a connection signal line SCL formed or provided from the semiconductor pattern. In one or more embodiments, the connection signal line SCL may be connected to the drain region DR of the transistor 100PC on a plane.

A first insulating layer 101 may be disposed or provided on the buffer layer BFL. The first insulating layer 101 may commonly overlap a plurality of pixels and cover the semiconductor pattern. The first insulating layer 101 may be an inorganic layer and/or an organic layer and have a single-layer or multi-layer structure. The first insulating layer 101 may include at least one of aluminum oxide, titanium oxide, silicon oxide, silicon nitride, silicon oxynitride, zirconium oxide, or hafnium oxide. In one or more embodiments, the first insulating layer 101 may be a single-layer silicon oxide layer. Not only the first insulating layer 101, but also the insulating layers of the circuit layer 120 to be described herein may be an inorganic layer and/or an organic layer and may have a single-layer or multi-layer structure. The inorganic layer may include at least one selected from among the materials as described in one or more embodiments, but embodiments of the present disclosure are not limited thereto.

A gate GT of the transistor 100PC may be disposed or provided on the first insulating layer 101. The gate GT may be a portion of a metal pattern. The gate GT may overlap the active region AL. In the process of doping the semiconductor pattern, the gate GT may function as a mask.

A second insulating layer 102 may be disposed or provided on the first insulating layer 101 and may cover the gate GT. The second insulating layer 102 may commonly overlap the pixels. The second insulating layer 102 may be an inorganic layer and/or an organic layer and have a single-layer or multi-layer structure. The second insulating layer 102 may include at least one of silicon oxide, silicon nitride, or silicon oxynitride. In one or more embodiments, the second insulating layer 102 may have a multi-layer structure including a silicon oxide layer and a silicon nitride layer.

A third insulating layer 103 may be disposed or provided on the second insulating layer 102. The third insulating layer 103 may have a single-layer or multi-layer structure. For example, the third insulating layer 103 may have a multi-layer structure including a silicon oxide layer and a silicon nitride layer.

A first connection electrode CNE1 may be disposed or provided on the third insulating layer 103. The first connection electrode CNE1 may be connected to the connection signal line SCL through a contact hole CNT-1 passing through the first to third insulating layers 10, 20, and 30.

A fourth insulating layer 104 may be disposed or provided on the third insulating layer 103. The fourth insulating layer 104 may be a single-layer silicon oxide layer. A fifth insulating layer 105 may be disposed or provided on the fourth insulating layer 104. In one or more embodiments, the fifth insulating layer 105 may be an organic layer, but embodiments of the present disclosure are not limited thereto.

A second connection electrode CNE2 may be disposed or provided on the fifth insulating layer 105. The second connection electrode CNE2 may be connected to the first connection electrode CNE1 through a contact hole CNT-2 passing through the fourth insulating layer 104 and the fifth insulating layer 105.

A sixth insulating layer 106 may be disposed or provided on the fifth insulating layer 105 and may cover the second connection electrode CNE2. In one or more embodiments, the sixth insulating layer 106 may be an organic layer, but embodiments of the present disclosure are not limited thereto.

An element layer 130 may be disposed or provided on the circuit layer 120. The element layer 130 may include light-emitting elements 100PER, 100PEG, and 100PEB. For example, each of the light-emitting elements 100PER, 100PEG, and 100PEB may include an organic light-emitting material, an inorganic light-emitting material, an organic-inorganic light-emitting material, a quantum dot, a quantum rod, a micro LED, or a nano LED. Hereinafter, as an example, each of the light-emitting elements 100PER, 100PEG, and 100PEB may be described as an organic light-emitting element, but embodiments of the present disclosure are not limited thereto.

The light-emitting elements 100PER, 100PEG, and 100PEB may include a first light-emitting element 100PER, a second light-emitting element 100PEG, and a third light-emitting element 100PEB. The first light-emitting element 100PER may include a first pixel electrode AER, a first light-emitting layer ELR, and a common electrode CE. The second light-emitting element 100PEG may include a second pixel electrode AEG, a second light-emitting layer ELG, and a common electrode CE. The third light-emitting element 100PEB may include a third pixel electrode AEB, a third light-emitting layer ELB, and a common electrode CE. The common electrode CE included in the first to third light-emitting elements 100PER, 100PEG, and 100PEB may be provided in an integrated shape. The first pixel electrode AER, the second pixel electrode AEG, and the third pixel electrode AEB may be referred to as a first electrode or anode. The common electrode CE may be referred to as a second electrode or cathode.

Hereinafter, the first light-emitting element 100PER is representatively described. The descriptions of the second light-emitting element 100PEG and the third light-emitting element 100PEB may be substantially the same as the description of the first light-emitting element 100PER. Hereinafter, the first pixel electrode AER may be referred to as a first electrode AER, the first light-emitting layer ELR may be referred to as a light-emitting layer ELR, and the common electrode CE may be referred to as a second electrode CE.

The first electrode AER may be disposed or provided on the sixth insulating layer 106. The first electrode AER may be connected to the second connection electrode CNE2 through a contact hole CNT-3 passing through the sixth insulating layer 106.

A pixel defining film 107 may be disposed or provided on the sixth insulating layer 106 and may cover a portion of the first electrode AER. A pixel defining opening 107-OP may be defined in the pixel defining film 107. The pixel defining opening 107-OP of the pixel defining film 107 may expose at least a portion of the first electrode AER.

The active region 1000A (see FIG. 1A) may include light-emitting regions PXAR, PXAG, and PXAB and a non-light-emitting region adjacent to the light-emitting regions PXAR, PXAG, and PXAB. The non-light-emitting region may be around (e.g., surround) the light-emitting regions PXAR, PXAG, and PXAB. In one or more embodiments, the light-emitting regions PXAR, PXAG, and PXAB may include a first light-emitting region PXAR, a second light-emitting region PXAG, and a third light-emitting region PXAB. The first to third light-emitting regions PXAR, PXAG, and PXAB may be defined to correspond to partial regions of the first electrodes AER, AEG, and AEB, respectively. The first light-emitting region PXAR may emit red light, the second light-emitting region PXAG may emit green light, and the third light-emitting region PXAB may emit blue light.

The light-emitting layers ELR, ELG, and ELB may be respectively disposed or provided on the first electrodes AER, AEG, and AEB. The light-emitting layer ELR may be disposed or provided in a region corresponding to the pixel defining opening 107-OP. For example, the light-emitting layers ELR, ELG, and ELB may be separately formed or provided in each of the pixels. If (e.g., when) the light-emitting layers ELR, ELG, and ELB are separately formed or provided in each of the pixels, each of the light-emitting layers ELR, ELG, and ELB may emit light of at least one color among blue, red, and green. However, embodiments of the present disclosure are not limited thereto, and the light-emitting layers ELR, ELG, and ELB may be connected to each other and commonly included in a plurality of light-emitting elements. In this case, the light-emitting layers ELR, ELG, and ELB may provide blue light or white light.

The second electrode CE may be disposed or provided on the light-emitting layers ELR, ELG, and ELB. The second electrode CE may have an integrated shape and be commonly included in a plurality of pixels.

A hole control layer may be disposed or provided between the first electrodes AER, AEG, and AEB and the light-emitting layers ELR, ELG, and ELB. The hole control layer may include a hole transport layer and may further include a hole injection layer. An electron control layer may be disposed or provided between the light-emitting layers ELR, ELG, and ELB and the second electrode CE. The electron control layer may include an electron transport layer and may further include an electron injection layer. The hole control layer and the electron control layer may be commonly formed or provided in a plurality of pixels by using an open mask or an inkjet process.

An encapsulation layer 140 may be disposed or provided on the element layer 130. The encapsulation layer 140 may include a first inorganic layer 141, an organic layer 142, and a second inorganic layer 143 which are sequentially stacked, but layers constituting the encapsulation layer 140 are not limited thereto. The first and second inorganic layers 141 and 143 may protect the element layer 130 from moisture and oxygen, and the organic layer 142 may protect the element layer 130 from foreign substances, such as dust particles. The first and second inorganic layers 141 and 143 may include a silicon nitride layer, a silicon oxynitride layer, a silicon oxide layer, a titanium oxide layer, an aluminum oxide layer, and/or the like. The organic layer 142 may include an acrylic-based organic layer, but embodiments of the present disclosure are not limited thereto.

A sensor layer 200 may be disposed or provided on the display layer 100. The sensor layer 200 may be referred to as a sensor, an input sensing layer, or an input sensing panel. The sensor layer 200 may include a sensor base layer 210, a first sensor conductive layer 220, a sensor insulating layer 230, a second sensor conductive layer 240, and a sensor protective layer 250.

The sensor base layer 210 may be directly disposed or provided on the display layer 100. The sensor base layer 210 may be an inorganic layer including at least one of silicon nitride, silicon oxynitride, or silicon oxide. In one or more embodiments, the sensor base layer 210 may be an organic layer including an epoxy resin, an acrylic resin, and/or an imide-based resin. The sensor base layer 210 may have a single-layer structure or a multi-layer structure in which layers are stacked along the third direction DR3.

Each of the first sensor conductive layer 220 and the second sensor conductive layer 240 may have a single-layer structure or a multi-layer structure in which layers are stacked along the third direction DR3.

The conductive layer having a single-layer structure may include a metal layer or a transparent (e.g., substantially transparent) conductive (e.g., electrically conductive) layer. The metal layer may include molybdenum (Mo), silver (Ag), titanium (Ti), copper (Cu), aluminum (Al), or an alloy thereof. The transparent conductive layer may include a transparent (e.g., substantially transparent) conductive (e.g., electrically conductive) oxide, such as an indium tin oxide, an indium zinc oxide, a zinc oxide, and/or an indium zinc tin oxide. In one or more embodiments, the transparent conductive layer may include a conductive (e.g., electrically conductive) polymer, such as poly(3,4-ethylenedioxythiophene) (PEDOT), metal nanowire, graphene, and/or the like.

The conductive layer having a multi-layer structure may include metal layers. The metal layers may have a three-layer structure of, for example, titanium/aluminum/titanium. The conductive layer having a multi-layer structure may include at least one metal layer and at least one transparent (e.g., substantially transparent) conductive (e.g., electrically conductive) layer.

The sensor insulating layer 230 may be disposed or provided between the first sensor conductive layer 220 and the second sensor conductive layer 240. The sensor insulating layer 230 may include an inorganic film. The inorganic film may include at least one of aluminum oxide, titanium oxide, silicon oxide, silicon nitride, silicon oxynitride, zirconium oxide, or hafnium oxide.

In one or more embodiments, the sensor insulating layer 230 may include an organic film. The organic film may include at least any one of an acrylic-based resin, a methacrylic-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

The sensor protective layer 250 may be disposed or provided on the sensor insulating layer 230 and cover the second sensor conductive layer 240. The second sensor conductive layer 240 may include a conductive (e.g., electrically conductive) pattern. The sensor protective layer 250 may cover the conductive (e.g., electrically conductive) pattern and reduce or eliminate the probability of damage occurring to the conductive pattern in a subsequent process. The sensor protective layer 250 may include an inorganic material. For example, the sensor protective layer 250 may include silicon nitride, but embodiments of the present disclosure are not limited thereto. In one or more embodiments, the sensor protective layer 250 may not be provided.

An optical layer 300 may be disposed or provided on the sensor layer 200. The optical layer 300 may include a light blocking layer 310, a plurality of color filters 320, and a planarization layer 330.

The light blocking layer 310 may be disposed or provided to overlap the conductive pattern of the second sensor conductive layer 240. The sensor protective layer 250 may be disposed or provided between the light blocking layer 310 and the second sensor conductive layer 240. The light blocking layer 310 may prevent the reflection of external light (or reduce a degree or occurrence of the reflection of external light) by the second sensor conductive layer 240. A material constituting the light blocking layer 310 is not particularly limited as long as the material can absorb light. The light blocking layer 310 may be a layer having a black color, and in one or more embodiments, the light blocking layer 310 may include a black coloring agent. The black coloring agent may include a black dye and/or a black pigment. The black coloring agent may include carbon black, a metal, such as chromium, and/or an oxide thereof.

A plurality of openings OPR, OPG, and OPB may be defined in the light blocking layer 310. The openings OPR, OPG, and OPB may overlap the first to third light-emitting layers ELR, ELG, and ELB, respectively, and may be referred to as first to third openings OPR, OPG, and OPB. The color filters 320 may include a first color filter 320R, a second color filter 320G, and a third color filter 320B. The first to third color filters 320R, 320G, and 320B may be disposed or provided to correspond to the first to third openings OPR, OPG, and OPB, respectively. The first to third color filters 320R, 320G, and 320B may transmit light provided from the first to third light-emitting layers ELR, ELG, and ELB overlapping the first to third color filters 320R, 320G, and 320B.

The planarization layer 330 may cover the light blocking layer 310 and the color filter 320. The planarization layer 330 may provide a flat (e.g., substantially flat) surface thereon. The planarization layer 330 may include an organic material. The planarization layer 330 may have a refractive index similar to a refractive index of a first film layer 410 to be described herein. For example, the difference between the refractive index of the planarization layer 330 and the refractive index of the first film layer 410 may be about 0.05 or less. For example, the planarization layer 330 may have a refractive index of about 1.54.

In one or more embodiments, the optical layer 300 may include a reflection control layer instead of the color filters 320. For example, in FIG. 5, the color filters 320 may not be provided, and the reflection control layer may be added in the place in which the color filters 320 are not provided. The reflection control layer may selectively absorb light in a partial band among light reflected from inside the display layer and/or the electronic device or light incident from outside the display layer and/or the electronic device.

A window 400 may be disposed or provided on the optical layer 300. The window 400 may protect the display layer 200 from the outside. In one or more embodiments, the window 400 may include a plurality of adhesive layers 401 and 402, a first film layer 410, a second film layer 420, and a protective layer 430 (or a first protective layer 430).

The first film layer 410 may be bonded to the upper surface of the planarization layer 330 with a first adhesive layer 401 between the first film layer 410 and the planarization layer 330. The refractive index of the first film layer 410 may be about 1.5 to about 1.52. The first film layer 410 may include glass and may be ultra-thin glass (UTG). For example, a thickness TK1 of the first film layer 410 may be about 1 mm or less. For example, the thickness TK1 of the first film layer 410 may be about 30 μm. Because the first film layer 410 is designed as a thin-film glass layer having the thickness TK1, it may be feasible to provide the window 400 that has impact resistance, flexibility, and improved or enhanced light transmittance.

The second film layer 420 may be bonded to the first film layer 410 with a second adhesive layer 402 between the second film layer 420 and the first film layer 410. A thickness TK2 of the second film layer 420 may be set or predetermined to be about 55 μm to about 75 μm and may be, for example, about 65 μm. By designing the thickness TK2 of the second film layer 420 to be within a set or predetermined range, the light transmittance of the window 400 may be improved or enhanced and the unevenness of light visible through the window 400 may be reduced, thereby improving or enhancing the external visibility of an image.

The refractive index of the second film layer 420 may be similar for each wavelength within the visible light range. For example, the minimum and maximum values of the refractive index of the second film layer 420 measured within the visible light range may exist within a similar range with a small deviation, and the similar range may be about 0.2 or less. Therefore, the second film layer 420 may be designed so that (e.g., such that) the deviation of the refractive index for each wavelength is about 0.2 or less within the visible light range. The refractive index of the second film layer 420 may vary depending on the material, the composition ratio and molecular structure of the material, the thickness of the second film layer 420, and/or the like. The second film layer 420 may be a polymer film composed of an organic material. The second film layer 420 may be a film composed of, for example, triacetyl cellulose (TAC), acrylic, and/or polycarbonate (PC).

In one or more embodiments, as long as the second film layer 420 has the foregoing refractive index range, the second film layer 420 may include a polyethylene terephthalate (PET) film with a primer whose refractive index is controlled or selected. For example, the second film layer 420 may include a polyethylene terephthalate film including a primer having a refractive index of about 1.47 to about 1.66. For example, if (e.g., when) the second film layer 420 includes the polyethylene terephthalate film, the refractive index of the primer may be limited to about 1.47 to about 1.66. A more detailed description thereof will be given herein.

In one or more embodiments, the second film layer 420 may have a refractive index similar to a refractive index of an adjacent layer, for example, the first film layer 410. The difference between the refractive index of the second film layer 420 and the refractive index of the first film layer 410 may be about 0.1 or less, and, for example, about 0.05 or less. According to the present disclosure, by designing the refractive index of the second film layer 420 to have a low deviation for each wavelength and to fall within a range similar to the refractive index of the first film layer 410, the reflectance of external light may be reduced, and, for example, the prominent reflection of blue light may be decreased, thereby improving or enhancing the visibility of the electronic device.

The protective layer 430 may be disposed or provided on the second film layer 420. The protective layer 430 may be the uppermost layer among the layers that forms or provides the window 400 and may be a layer configured or arranged to provide the outer surface of the window 400. The protective layer 430 may have sufficient or suitable rigidity to protect the display surface of the electronic device 1000.

The protective layer 430 may include an organic material. In one or more embodiments, the protective layer 430 may be in contact with the second film layer 420. In this case, the protective layer 430 may be formed or provided by depositing and/or coating an organic material on the upper surface of the second film layer 420. Accordingly, an adhesive layer may not be provided between the protective layer 430 and the second film layer 420. In one or more embodiments, this is illustrated merely as an example, and the protective layer 430 may be provided in the form of a film and bonded to the second film layer 420 by an adhesive layer or may be provided in the form of being coated on an adhesive layer and attached to the second film layer 420. The protective layer 430 according to one or more embodiments may be provided in one or more embodiments, and embodiments of the present disclosure are not limited thereto.

A thickness TK3 of the protective layer 430 may be smaller than the thickness TK2 of the second film layer 420. The thickness TK3 of the protective layer 430 may be set or predetermined to be about 55 μm to about 75 μm, for example, about 65 μm. By designing the thickness TK3 of the protective layer 430 to be within a set or predetermined range, the light transmittance of the window 400 may be improved or enhanced and the unevenness of light visible through the window 400 may be reduced, thereby improving or enhancing the external visibility of an image.

The protective layer 430 may have a refractive index similar to a refractive index of the first film layer 410. The difference between the refractive index of the protective layer 430 and the refractive index of the first film layer 410 may be about 0.1 or less, and, for example, about 0.05 or less. According to the present disclosure, by designing the refractive index of the protective layer 430 to be within a range similar to the refractive index of the first film layer 410, the reflectance of external light may be reduced and, for example, the prominent reflection of blue light may be decreased, thereby improving or enhancing the visibility of the electronic device.

The protective layer 430 may further include a low reflection layer. The refractive index of the low reflection layer may be about 1.48 or less. The thickness of the low reflection layer may be about 10 nm to about 200 nm. In one or more embodiments, the protective layer 430 may further include an anti-fingerprint layer. For example, the protective layer 430 may have a structure in which two or more layers are stacked.

In one or more embodiments, each of the first and second adhesive layers 401 and 402 constituting the window 400 may be a pressure-sensitive adhesive layer. A thickness TK01 of the first adhesive layer 401 or a thickness TK02 of the second adhesive layer 402 may be smaller than a thickness of the second film layer 420. Each of the thickness TK01 of the first adhesive layer 401 and the thickness TK02 of the second adhesive layer 402 may be about 50 μm. If (e.g., when) the thickness TK01 of the first adhesive layer 401 and the thickness TK02 of the second adhesive layer 402 become excessively or substantially large, light transmittance may be reduced and bending characteristics may be degraded. If (e.g., when) the thickness TK01 of the first adhesive layer 401 and the thickness TK02 of the second adhesive layer 402 become excessively or substantially small, delamination between layers may occur or impact resistance may be reduced, thereby decreasing reliability. According to the present disclosure, by designing the thickness TK01 of the first adhesive layer 401 and the thickness TK02 of the second adhesive layer 402 to be within a set or predetermined range, it may be feasible to provide the window 400 having sufficient or suitable impact resistance and improved or enhanced visibility.

The first and second adhesive layers 401 and 402 may have a refractive index similar to a refractive index of an adjacent layer. For example, the first and second adhesive layers 401 and 402 may have a refractive index similar to a refractive index of the first film layer 410. The difference between the refractive index of each of the first and second adhesive layers 401 and 402 and the refractive index of the first film layer 410 may be about 0.1 or less, and, for example, about 0.05 or less. According to the present disclosure, by designing the refractive indices of the first and second adhesive layers 401 and 402 to have a low deviation for each wavelength and to be similar to the refractive indices of adjacent layers, the reflectance of external light may be reduced, and, for example, the prominent reflection of blue light may be decreased, thereby improving or enhancing the visibility of the electronic device.

In one or more embodiments, the outermost film of the window 400 may have sufficient or suitable hardness to protect lower components, such as a display panel. For example, in one or more embodiments, the outermost film may be the second film layer 420, and the second film layer 420 may have a nanoindenter vickers hardness of about 35 Hv or more and a crack strain of about 2% or more. By selecting a film having sufficient or suitable hardness as the outermost film, the window 400 may stably or suitably provide the function of the window 400 that protects the display panel.

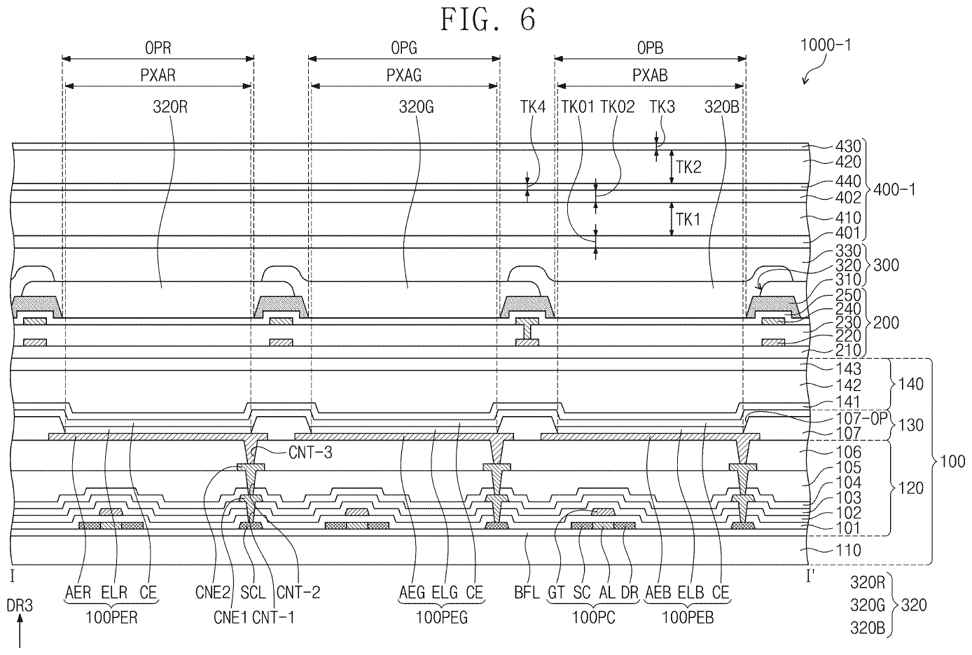

FIG. 6 is a cross-sectional view illustrating a portion of an electronic device according to one or more embodiments. FIG. 6 illustrates a region corresponding to FIG. 5. The electronic device 1000-1 as illustrated in FIG. 6 may include a window 400-1 having a different layer structure, compared to the electronic device 1000 as illustrated in FIG. 5. Hereinafter, duplicate descriptions may not be provided.

Referring to FIG. 6, the window 400-1 may further include additional protective layer 440 (hereinafter a second protective layer 440) separated from the first protective layer 430. The second protective layer 440 may be disposed or provided between the second adhesive layer 402 and the second film layer 420. A thickness TK4 of the second protective layer 440 may be set or predetermined to be within a range of about 5 μm to about 50 μm.

If (e.g., when) the second film layer 420 is composed of a material having a high water vapor transmission rate (WVTR), the second protective layer 440 may prevent defects (or reduce a degree or occurrence of defects) in the second film layer 420 and improve or enhance the reliability of the window 400-1. For example, if (e.g., when) the second film layer 420 is provided as a TAC film, the second film layer 420 may have a high water vapor transmission rate of about 1000 or more, which may reduce durability in a high temperature and high humidity environment. According to the present disclosure, by further including the second protective layer 440, defects due to moisture permeability may be prevented (or a degree or occurrence of defects due to moisture permeability may be reduced).

The second protective layer 440 may include an organic material. The second protective layer 440 may be provided in the form of a film. In this case, an additional adhesive layer may further be disposed or provided between the second protective layer 440 and the second film layer 420. The second protective layer 440 may include, for example, polyethylene terephthalate (PET), acrylic, a cycloolefin polymer (COP), polyimide (PI), polyethylene naphthalate (PEN), and/or polyamide (PA). However, these are described as an example, and the second protective layer 440 may be directly formed or provided through coating below the second film layer 420.

In one or more embodiments, the second protective layer 440 may include an elastomeric material, such as polyurethane (PU), polyester, and/or acryl foam. In this case, the modulus of the second protective layer 440 may be about ½ or less of the modulus of the second film layer 420. The modulus of the second protective layer 440 may be about 1 GPa or less. Accordingly, sufficient or suitable impact resistance to protect a lower layer may be secured.

In the present disclosure, the modulus may refer to an elastic modulus. For example, the modulus may be defined as a ratio of stress to strain. For example, the modulus of the second protective layer 440 may correspond to the slope of an elastic section below a yield stress value in a stress-strain graph obtained from a tensile or shear test conducted on the second protective layer 440. For example, the modulus of the second protective layer 440 may correspond to a value obtained by dividing the stress, which is a force applied per unit area to the second protective layer 440, by the strain, which is a strain value per unit length. Hereinafter, the modulus of each layer may correspond to the elastic modulus and will be referred to as a modulus for easy explanation.

In one or more embodiments, in this case, although an additional protective layer, such as a damping layer, is not further disposed or provided between the optical layer 300 and the first film layer 410, the lower layers of the electronic device 1000-1, for example, the display layer 100 or the sensor layer 200, may be stably protected. In the case of the damping layer, which has a thickness of about 100 μm, the addition of the damping layer may improve or enhance the impact resistance of the electronic device 1000-1, but the thickness of the electronic device 1000-1 may increase.

According to the present disclosure, by including the window 400-1 having improved or enhanced impact resistance, the electronic device 1000-1 may secure sufficient or suitable impact resistance, thus being able to provide the electronic device 1000-1 having a low thickness.

In one or more embodiments, the second protective layer 440 may further include fluorine as an additive. Then, as the water-repellent property of the second protective layer 440 is improved or enhanced, damage to the window 400-1 due to moisture permeability and/or the like may be prevented (or a degree or occurrence of damage to the window 400-1 due to moisture permeability and/or the like may be reduced).

In one or more embodiments, the window 400-1 may not include an additional film layer by further including the second protective layer 440. For example, even without an additional film layer between the first adhesive layer 401 and the optical layer 300, the window 400-1 may secure sufficient or suitable impact resistance, and the issue of reduced light transmittance due to the addition of a film layer may be mitigated. Accordingly, the window 400-1 may minimize or reduce the number of second film layers 420, thus being able to provide the electronic device 1000-1 having improved or enhanced external visibility.

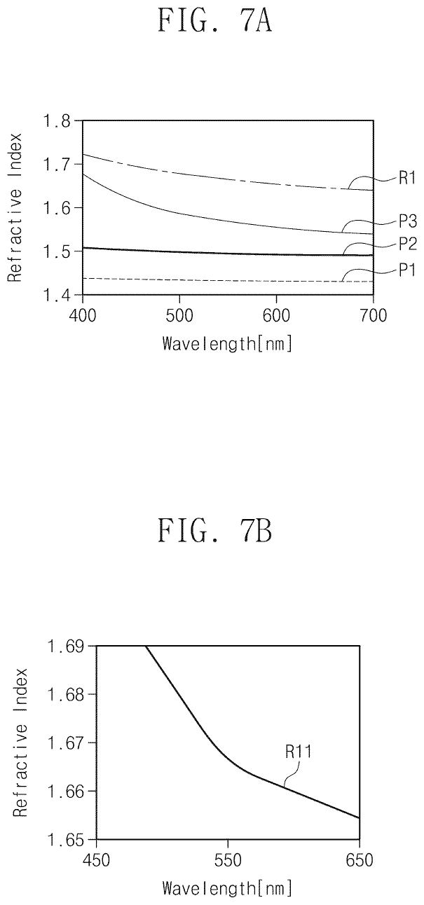

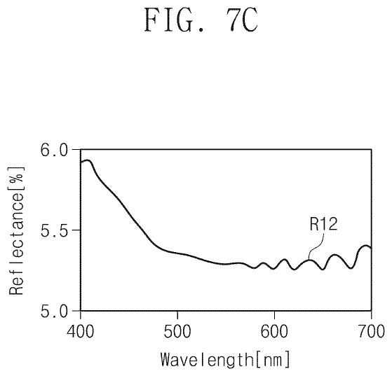

FIG. 7A is a graph illustrating changes in refractive index according to the wavelengths of layers constituting the optical layer. FIG. 7B is a graph illustrating changes in refractive index according to the wavelengths of Comparative Embodiment, and FIG. 7C is a graph illustrating changes in reflectance according to the wavelengths of Comparative Embodiment.

In FIG. 7A, a first graph R1 illustrates changes in refractive index according to the wavelengths of a film layer composed of polyethylene terephthalate (PET), a second graph P1 illustrates changes in refractive index according to the wavelengths of a film layer composed of polyimide (PI), a third graph P2 illustrates changes in refractive index according to the wavelengths of a film layer composed of glass, and a fourth graph P3 illustrates changes in refractive index according to the wavelengths of a film layer composed of triacetyl cellulose (TAC). A graph R11 as illustrated in FIG. 7B illustrates changes in refractive index according to the wavelengths of a film layer composed of polyethylene terephthalate (PET). A graph R12 as illustrated in FIG. 7C illustrates changes in reflectance according to the wavelengths of a film layer composed of polyethylene terephthalate (PET). The film layers composed of polyethylene terephthalate (PET) as described in FIGS. 7A to 7C may be comparative embodiments in which a primer is not controlled. Hereinafter, one or more embodiments of the present disclosure will be described in more detail with reference to FIGS. 7A to 7C.

Referring to FIGS. 7A and 7B, it can be observed that the film layers composed of polyethylene terephthalate (PET) exhibit a relatively prominent refractive index deviation according to wavelength. The film layer composed of polyethylene terephthalate (PET) has a refractive index of about 1.7 at a wavelength of about 450 nm and a refractive index of about 1.66 or less at a wavelength of about 650 nm, so it can be observed that the refractive index deviation according to the wavelengths of the film layer composed of polyethylene terephthalate (PET) is about 0.04 particularly within the wavelength range of about 450 nm to about 650 nm. Also, referring to the second graph P1 for the film layer composed of polyimide (PI), it can be observed that the deviation is about 0.15. Referring to FIG. 7C, the film layer composed of polyethylene terephthalate (PET) has a deviation in reflectance, varying within the range of about 5% to about 6%.

Referring to FIG. 7A, the third and fourth graphs P2 and P3 have relatively lower deviations than the first graph R1 or the second graph P1. Referring to the third graph P2, it can be observed that the film layer composed of glass has a uniform (e.g., substantially uniform) refractive index of about 1.5 within the wavelength range of about 400 nm to about 700 nm and has similar refractive indices by wavelength with almost no deviation. Referring to the fourth graph P3, it can be observed that the film layer composed of TAC has a uniform (e.g., substantially uniform) refractive index of about 1.42 within the wavelength range of about 400 nm to about 700 nm and has similar refractive indices by wavelength with almost no deviation.

Table 1 shows the reflectances of the film layer composed of polyethylene terephthalate (PET) and the film layer composed of TAC, and the proportion a* of red light and the proportion b* of blue light among light reflected from the film layer.

TABLE 1

| | | Comparative | First |
|---|---|---|---|
| | | Embodiment | Embodiment |
| Reflectance (%) | SCI | 3.8 −0.3, −2.5 | 3.7 −0.5, −1.2 |
| a* and b* | SCE | 0.8 −1.5, −4.9 | 0.7 −1.1, −3.0 |

Referring to Table 1, it can be observed that the proportion of reflected blue light b* has significantly decreased in both the reflectance measured by a specular component included factor (SCI) method and the reflectance measured by a specular component excluded factor (SCE) method. The reflectance in the SCI method may refer to a reflectance measured from light including specularly reflected light, while the reflectance in the SCE method may refer to a reflectance measured from light excluding specularly reflected light and including only diffusely reflected light (including scatteredly reflected light). The a* index and the b* index represent the proportion of red light and the proportion of blue light in the chromaticity meter, respectively, and as the b* index decreases, the reflectance of blue light, e.g., short-wavelength light, increases, causing the reflected light to appear bluish. Referring to Table 1, it can be observed that the reflectance in the SCI method and the reflectance in the SCE method are substantially similar to each other, with only a difference of about 0.1% in Comparative Embodiment and First Embodiment, respectively. However, if (e.g., when) looking at the b* index, it was found to increase by about 1.3 in the SCI method and by about 1.9 in the SCE method. For example, it can be observed that in First Embodiment including the film layer composed of TAC, the reflection proportion of blue light was relatively significantly reduced, and as a result, the ratio of short-wavelength light in the reflected light was reduced although the change in the amount of reflected light itself was not large. Accordingly, a phenomenon in which the reflected light appears bluish in First Embodiment may be reduced compared to Comparative Embodiment.

According to the present disclosure, a window may be formed or provided with film layers made of materials having similar refractive indices by wavelength. In this case, an issue in which the reflectance of short-wavelength light among the reflected light is prominent may be improved, so that (e.g., such that) the reflectance by wavelength may be relatively or substantially uniform. Accordingly, the tendency for the reflected light emitted from the window 400 to appear bluish may be reduced, thus being able to provide an electronic device with improved or enhanced uniformity of color.

Table 2 shows the results of measuring the refractive indices for each layer of the window as illustrated in FIG. 5 and the reflectance of the window.

TABLE 2

| | Comparative | First | Second |
|---|---|---|---|
| | Embodiment | Embodiment | Embodiment |
| Refractive Index | 1.52 | 1.52 | 1.52 |
| of Protective | | | |
| Layer | | | |
| Refractive Index | 1.66 | 1.49 | 1.52 |
| of Second Film | | | |
| Layer | | | |
| Refractive Index | 1.47 | 1.47 | 1.52 |
| of Second | | | |
| Adhesive Layer | | | |
| Refractive Index | 1.51 | 1.51 | 1.52 |
| of First Film | | | |
| Layer | | | |
| Refractive Index | 1.47 | 1.47 | 1.52 |
| of First Adhesive | | | |
| Layer | | | |
| Refractive Index | 1.54 | 1.54 | 1.54 |
| of Planarization | | | |
| Layer | | | |
| Reflectance (SCI) | 6.40% | 5.98% | 5.90% |

Comparative Embodiment may be a window having a stacked structure of a planarization layer 330 having a refractive index of about 1.54, a first adhesive layer 401 having a refractive index of about 1.47, a first film layer 410 having a refractive index of about 1.51, a second adhesive layer 402 having a refractive index of about 1.47, a second film layer 420 having a refractive index of about 1.66, and a protective layer 430 having a refractive index of about 1.52. First Embodiment may be a window in which the refractive index of the second film layer 420 is designed differently from the refractive index of Comparative Embodiment, and Second Embodiment may be a window in which all layers are designed to have substantially the same refractive index as the protective layer of Comparative Embodiment. Referring to Table 2, the SCI reflectance measured by including both specularly reflected light and diffusely reflected light is relatively lower in First Embodiment and Second Embodiment than in Comparative Embodiment. For example, as in First Embodiment, by controlling the refractive index of the second film layer 420 to have a relatively small deviation from adjacent layers, for example, the second adhesive layer 402 or the protective layer 430, the reflectance of external light itself is also reduced.

Also, as in Second Embodiment, by controlling the layers constituting the window to have substantially the same refractive index, the reflectance of external light may further be reduced. For example, according to the present disclosure, by reducing the difference in refractive index between adjacent layers or designing the refractive indices to be similar to each other, the reflectance of the window may be reduced and the display characteristics may be improved or enhanced.

In one or more embodiments, the film layer 420 according to one or more embodiments may include polyethylene terephthalate including a primer whose refractive index is controlled. The film layer 420 may include polyethylene terephthalate including a primer whose refractive index is controlled to be in the range of about 1.47 to about 1.66. Table 3 describes the values measured by the SCI method and the SCE method for the reflectance and the a and b* indices. In Table 3, Third Embodiment may be a film layer including polyethylene terephthalate including a primer whose refractive index is controlled to be about 1.58, and Comparative Embodiment may be a film layer including polyethylene terephthalate including a primer having a refractive index outside the range of about 1.47 to about 1.66.

TABLE 3

| | | Comparative | Third |
|---|---|---|---|
| | | Embodiment | Embodiment |
| SCI Method | Reflectance (%) | 3.8 | 3.8 |
| | a* Index, b* Index | −0.9, −4.4 | −1.0, −3.0 |
| SCE Method | Reflectance (%) | 0.7 | 0.7 |
| | a* Index, b* Index | −0.9, −5.4 | −1.2, −4.3 |

Referring to Table 3, the reflectances of Comparative Embodiment and the film layer 420 measured by the SCI method are both about 3.8%, and the reflectances thereof measured by the SCE method are both about 0.7%, showing identical results. In contrast, it can be observed that the a* index and the b* index are different from each other in Comparative Embodiment and the film layer 420. For example, the b* index measured by the SCI method is about-3.0 for the film layer 420, which is an increase of about 1.4 compared to Comparative Embodiment. Also, the b* index measured by the SCE method is about-4.3 for the film layer 420, which is an increase of about 1.1 compared to Comparative Embodiment. For example, because the reflection proportion of blue light in the light reflected from the film layer 420 including a primer whose refractive index is controlled is relatively significantly reduced, it can be observed that although the change in the amount of reflected light itself is not large, the ratio of short-wavelength light in reflected light is reduced. Accordingly, in Third Embodiment, a phenomenon in which reflected light appears bluish may be reduced compared to Comparative Embodiment. According to the present disclosure, if (e.g., when) the refractive index of the primer is designed to be within a set or predetermined range, polyethylene terephthalate may be used as the film layer 420, thus being able to provide an electronic device with improved color of reflected light and sufficient or suitable rigidity.

According to the present disclosure, the electronic device may reduce the reflectance of external light and alleviate the problem of causing color imbalance due to increased reflectance of specific light. Accordingly, as color appearance is improved or enhanced, the display quality of the electronic device may be enhanced.

Although one or more embodiments of the present disclosure have been described, those skilled in the art or those of ordinary skill in the art will understand that one or more suitable modifications and changes may be made to the embodiments within the scope that does not depart from the spirit and scope of the present disclosure. Accordingly, the scope of the present disclosure should not be limited to the embodiments as described in the detailed description of the present disclosure, but should be determined by the appended claims and equivalents thereof.

What is claimed is:

1. A display device comprising:
a display layer comprising a plurality of light-emitting elements;
an optical layer on the display layer; and
a window on the optical layer,
wherein:
the optical layer comprises a light blocking layer having a plurality of openings defined therein and corresponding to a plurality of light-emitting regions and a plurality of color filters disposed to correspond to the plurality of openings, respectively;
the window comprises a thin film glass layer, a film layer provided on the thin film glass layer and having a first refractive index, a first protective layer provided on the film layer and having a second refractive index, and an adhesive layer in contact with any one selected from among the thin film glass layer, the film layer, and the first protective layer and having a third refractive index; and
a difference between a maximum value and a minimum value of the first refractive index measured within a wavelength range of 450 nm to 650 nm is 0.2 or less.

2. The display device as claimed in claim 1, wherein, on substantially the same wavelength, a difference between a refractive index of the thin film glass layer and each of the first refractive index, the second refractive index, and the third refractive index is 0.05 or less.

3. The display device as claimed in claim 2, wherein:
the adhesive layer is in contact with each of the film layer and the thin film glass layer; and
a thickness of the adhesive layer is 50 μm or less.

4. The display device as claimed in claim 1, further comprising a second protective layer below the film layer,
wherein the film layer comprises triacetyl cellulose (TAC).

5. The display device as claimed in claim 4, wherein:
the optical layer further comprises a planarization layer covering the plurality of color filters and the light blocking layer; and
the adhesive layer is between the film layer and the planarization layer and in contact with the planarization layer.

6. The display device as claimed in claim 5, further comprising fluorine in the second protective layer.

7. The display device as claimed in claim 5, wherein the second protective layer has elasticity.

8. The display device as claimed in claim 7, wherein a modulus of the second protective layer is ½ or less of a modulus of the film layer.

9. The display device as claimed in claim 5, wherein a thickness of the second protective layer is 5 μm to 50 μm.

10. The display device as claimed in claim 5, wherein, on substantially the same wavelength, a difference between a refractive index of the planarization layer and the first refractive index of the film layer is 0.05 or less.

11. The display device as claimed in claim 1, wherein:
the first protective layer is in contact with the film layer; and
a thickness of the first protective layer is 5 μm or less.

12. The display device as claimed in claim 1, wherein, on substantially the same wavelength, the first refractive index, the second refractive index, and the third refractive index are substantially the same as each other.

13. An electronic device, comprising:
a plurality of housing units, each providing a predetermined accommodation space;
a hinge unit provided between the plurality of housing units and connecting the plurality of housing units to each other; and
a display device in the predetermined accommodation space,
wherein the display device comprises:
a display layer comprising a plurality of light-emitting elements;
an optical layer on the display layer; and
a window on the optical layer,
wherein:
the optical layer comprises a light blocking layer having a plurality of openings defined therein and corresponding to a plurality of light-emitting regions, a plurality of color filters disposed to correspond to the plurality of openings, respectively, and a planarization layer covering the plurality of color filters; and
the window comprises a thin film glass layer, a film layer provided on the thin film glass layer and having a first refractive index, a first protective layer disposed on the film layer and having a second refractive index, and an adhesive layer in contact with at least any one of the thin film glass layer, the film layer, or the first protective layer and having a third refractive index,
wherein, on substantially the same wavelength, each of a difference between a refractive index of the planarization layer and the first refractive index of the film layer and a difference between a refractive index of the thin film glass layer and the first refractive index of the film layer is 0.05 or less.

14. The electronic device as claimed in claim 13, wherein, on substantially the same wavelength, a difference between the third refractive index and the refractive index of the thin film glass layer is 0.05 or less.

15. The electronic device as claimed in claim 13, wherein a difference between a maximum value and a minimum value of the first refractive index measured within a wavelength range of 450 nm to 650 nm is 0.2 or less.

16. The electronic device as claimed in claim 13, further comprising a second protective layer between the film layer and the optical layer,
wherein the adhesive layer is in contact with each of the second protective layer and the planarization layer.

17. The electronic device as claimed in claim 16, wherein a thickness of the second protective layer is 5 μm to 50 μm.

18. The electronic device as claimed in claim 16, wherein the first protective layer is in contact with the film layer.

19. The electronic device as claimed in claim 13, wherein a thickness of the thin film glass layer is 30 μm or less.

20. The electronic device as claimed in claim 13, wherein, on substantially the same wavelength, each of the first refractive index, the second refractive index, and the third refractive index is substantially equal to the refractive index of the thin film glass layer.
